(19) United States
(12) Patent Application Publication
(10) Pub. No.: US 2026/0156789 A1
(43) Pub. Date: Jun. 4, 2026

(54) COPPER FOAM THERMOELECTRIC HEAT EXCHANGER FOR USE IN DATA CENTER COOLING

(71) Applicant: Cisco Technology, Inc., San Jose, CA (US)

(72) Inventors: Keihl Meneses Mangalindan, San Jose, CA (US); Sabine Alison Laurence, San Jose, CA (US); Angela Siqi Cai, San Jose, CA (US); Aakash Daksh, Lafayette, IN (US)

(21) Appl. No.: 18/966,536

(22) Filed: Dec. 3, 2024

(51) Int. Cl. H05K 7/20

(52) U.S. Cl. CPC H05K 7/20836; H05K 7/20418

(57) ABSTRACT

In one embodiment, an apparatus includes a chassis, one or more heat-generating components, and a thermoelectric heat exchanger. The one or more heat-generating components is carried on the chassis and arranged to generate heat. The thermoelectric heat exchanger is carried on the chassis, and includes copper foam and at least one thermoelectric generator (TEG), wherein the copper foam is arranged to absorb a first portion of the generated heat, and wherein the at least one TEG is configured to convert the first portion of the generated heat into electrical energy.

### TECHNICAL FIELD

The present disclosure relates to efficiently cooling data centers or computer rooms.

### BACKGROUND

The performance of hardware such as network equipment may be compromised by heat. For example, the performance system hardware that is contained in a box may be compromised by excessive heat. As such, in order to reduce the effects of heat on the performance of system hardware, heat transfer out of a box/housing containing the system hardware may be substantially optimized with silicon placement and heat sink selection.

Typically, system hardware in a box is placed on racks, e.g., server racks, in a data center or a computer room. While cooling within the box is generally addressed with silicon placement and heat sink selection, efficiently cooling the data center may be difficult. Heat emanating from the box is generally diffused into a large, open space. Although the use of computer room air conditioners (CRACs) in a data center allows for cooling the data center, the cooling is inefficient due to the mixing of cold air from the CRAC and hot air from boxes. While solutions such as liquid cooling and immersion cooling may improve the efficiency with which a data center may be cooled, such solutions are expensive and often difficult to implement. As the use of servers, as for example artificial intelligence (AI) servers and other equipment in a data center continues to increase, the ability to efficiently cool data centers is becoming more relevant for data center operations.

### BRIEF DESCRIPTION OF THE DRAWINGS

The disclosure will be readily understood by the following detailed description in conjunction with the accompanying drawings in which:

FIG. 1 is a diagrammatic representation of a data center which includes copper foam thermoelectric heat exchangers mounted on server racks in accordance with an embodiment.

FIG. 2 is a process flow diagram which illustrates a method of cooling switches and servers mounted on a server rack in a data center in accordance with an embodiment.

FIG. 3 is a diagrammatic representation of a data center, e.g., data center 100 of FIG. 1, which indicates a flow of cool air in accordance with an embodiment.

FIG. 4 is a diagrammatic representation of a data center, e.g., data center 100 of FIG. 1, which indicates a flow of warm air in accordance with an embodiment.

FIG. 5 is a diagrammatic representation of hot air partially absorbed by a copper foam thermoelectric heat exchanger such that warm air passes out of the copper foam thermoelectric heat exchanger in accordance with an embodiment.

FIG. 6 is a block diagram representation of a copper foam thermoelectric heat exchanger in accordance with an embodiment.

FIG. 7 is a diagrammatic representation of a flow of air and energy with respect to a server rack and a copper foam thermoelectric heat exchanger in accordance with an embodiment.

FIG. 8 is a diagrammatic representation of an energy arrangement, e.g., energy arrangement 756 of FIG. 7, in accordance with an embodiment.

FIG. 9 is a process flow diagram which illustrates a method of causing harvested energy to be stored, e.g., optional step 225 of FIG. 2, in accordance with an embodiment.

FIG. 10 is a process flow diagram which illustrates a method of using energy obtained from a copper foam thermoelectric heat exchanger in accordance with an embodiment.

FIG. 11 is a hardware block diagram of a networking/computing device/apparatus/appliance/endpoint that may be cooled using techniques described with respect to FIGS. 1-10.

### DETAILED DESCRIPTION

### Overview

Techniques are presented herein that enable data centers which contain racks of system hardware to be cooled efficiently, substantially without investing in solutions that are expensive and/or difficult to implement, e.g., liquid cooling and/or immersion cooling solutions. A copper foam thermoelectric heat exchanger may be coupled to or otherwise positioned on server racks to substantially absorb and to localize heat generated by system hardware such a servers and/or switches that are placed in the server racks. When heat emanating from or otherwise emitted from servers and/or switches housed on a server rack is at least partially absorbed by a copper foam thermoelectric heat exchanger, the requirements for a computer room air conditioner (CRAC), e.g., a load on the CRAC, may be reduced. In some instances, the absorbed heat may effectively be converted to electrical energy that is stored and used by system hardware. That is, the heat-generating elements located on a server rack such as servers and/or switches may effectively consume electrical energy derived or otherwise obtained from heat generated by the heat-generating elements.

According to one aspect, an apparatus includes a chassis, one or more heat-generating components, and a thermoelectric heat exchanger. The one or more heat-generating components is carried on the chassis and arranged to generate heat. The thermoelectric heat exchanger is carried on the chassis, and includes copper foam and at least one thermoelectric generator (TEG), wherein the copper foam is arranged to absorb a first portion of the generated heat, and wherein the at least one TEG is configured to convert the first portion of the generated heat into electrical energy.

In accordance with another embodiment, an apparatus includes a thermoelectric heat exchanger and an energy arrangement. The thermoelectric heat exchanger includes copper foam and at least one thermoelectric generator (TEG), the at least one TEG being embedded in the copper foam, the copper foam being arranged to absorb a first portion of heat, wherein the at least one TEG is configured to convert the first portion of the generated heat into electrical energy and wherein a second portion of the heat passes through the copper foam. The energy arrangement includes a DC-DC converter and a battery bank, and is arranged to obtain the electrical energy (power) and to store the electrical energy in the battery bank.

According to yet another embodiment, a method includes obtaining, at a thermoelectric heat exchanger carried on a chassis, heat generated by a heat-generating component carried on the chassis, wherein the thermoelectric heat exchanger includes copper foam and at least one thermoelectric generator (TEG) embedded in the copper foam. The method also includes absorbing a first portion of the heat in the copper foam, and converting, using the at least one TEG, the first portion of the heat absorbed in the copper foam into electrical energy. The electrical energy is provided from the at least one TEG to an energy arrangement, the energy arrangement being carried on the chassis, wherein the energy arrangement includes a battery bank. The method also includes storing the electrical energy in the battery bank.

### Example Embodiments

The ability to efficiently cool server racks in data centers is critical to ensure the performance of components, e.g., system hardware such as switches and servers, located on the server racks. Computer room air conditioners (CRACs) are used in data centers for cooling purposes, but the efficiency with which CRACs may cool data centers is inefficient due to the mixing of cold air from the CRAC and hot air generated by the system hardware.

By absorbing heat produced by system hardware as the heat exits the system hardware, the efficiency with which CRACs may cool data centers may be improved as the temperature of the heated air may be reduced. In one embodiment, a server rack may include a thermoelectric heat exchanger that is arranged to absorb heat that is outputted from system hardware located on the server rack. The thermoelectric heat exchanger may effectively lower the temperature of hot air that exits the system hardware by absorbing some of the heat in the hot air.

A thermoelectric heat exchanger that is mounted or otherwise positioned substantially directly on a server rack or chassis may be formed from copper foam and include one or more thermoelectric generators (TEGs), or devices configured to convert heat, or heat flux, into electrical energy. The one or more TEGs may be substantially embedded in, or otherwise incorporated into, the copper foam. A thermoelectric heat exchanger that includes copper foam and TEGs, and is positioned on a server rack in a data center, may absorb some portion of heat generated by or emanating from system hardware located on the server rack to effectively lower the temperature of air that exits the server rack into aisles in the data center. The TEGs may convert heat absorbed by the copper foam into electrical energy, which may then be use for purposes including, but not limited to including, powering system hardware in the data center.

In general, a data center may be any physical location in which system hardware may be situated. For example, a data center may be a room that contains system hardware positioned on racks. Racks may generally be frames, enclosures, shelves, and the like that are configured to support system hardware. System hardware may include, but is not limited to including, switches and/or computer systems such as servers.

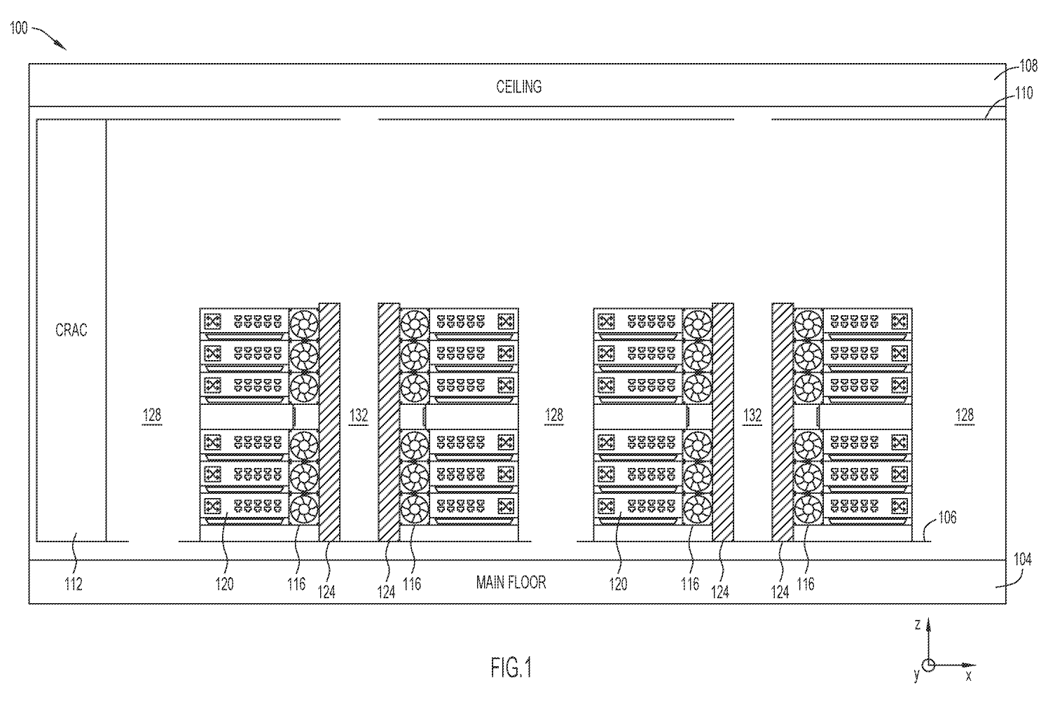

FIG. 1 is a diagrammatic representation of a data center which includes copper foam thermoelectric heat exchangers mounted on server racks in accordance with an embodiment. A data center 100 includes a main floor 104, a raised floor 106, a ceiling 108, and a dropped ceiling 110. Raised floor 106 is arranged over main floor 104 to enable air to be circulated substantially beneath one or more server racks 116. Dropped ceiling 110 may be arranged below ceiling 108, and effectively functions as a return air plenum.

A CRAC 112 is located in data center 100, and arranged to provide cooling capabilities within data center 100 by cooling air. As mentioned above, one or more server racks 116 may be positioned over raised floor 106 such that cooled air may circulate substantially beneath one or more server racks 116. Server racks 116 may include one or more system hardware boxes 120 or system hardware chassis. System hardware boxes 120 may generally include any hardware that is arranged to generate heat, e.g., heat generated substantially as a byproduct of the operation of the hardware. System hardware boxes 120 may contain, but are not limited to containing, hardware such as switches and/or servers. It should be appreciated that the number of server racks 116 and system hardware boxes 120 included in data center 100 may vary widely.

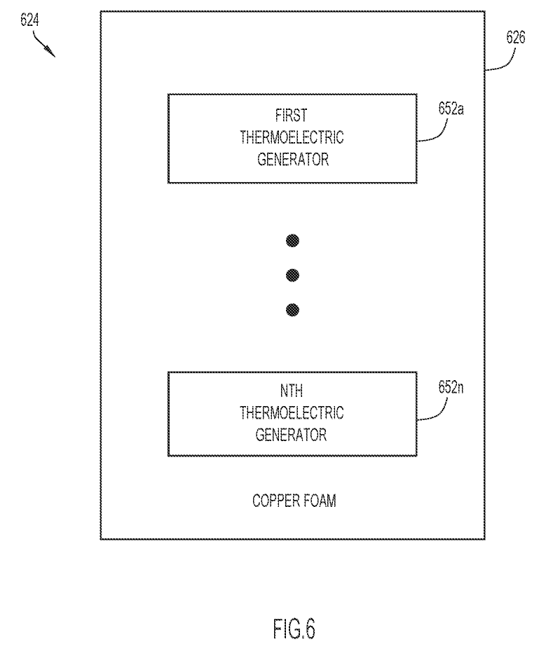

Each server rack 116 has a copper foam thermoelectric heat exchanger 124 positioned thereon or coupled thereto. That is, copper foam thermoelectric heat exchanger 124 is located on server rack 116 to absorb at least some portion or heat emanating from, or otherwise emitted by, system hardware boxes 120 located on server rack 116. Typically, hot or heated air is exhausted from a back of system hardware boxes 120. In one embodiment, copper foam thermoelectric heat exchanger 124 includes copper foam in which at least one TEG is embedded, as will be discussed in more detail below with respect to FIG. 6.

Within data center 100, aisles 128 and aisles 132 may be located between adjacent server racks 116. As shown, aisles 128 are cold or air aisles and aisles 132 are hot or warm air aisles. The air flow through aisles 128 generally includes cold air from CRAC 112, while the air flow through aisles 132 generally includes heated or warmed air, or air that is warmed by heat generated by system hardware boxes 120 that may not be absorbed by copper foam thermoelectric heat exchangers 124 located on server racks 116. That is, a portion of heated air that is not substantially absorbed by copper foam thermoelectric heat exchangers 124 may effectively be exhausted into aisles 132 as warm air. Air in aisles 128 may generally be between approximately five degrees Celsius and approximately twenty degrees Celsius, while air in aisles 132 may be approximately fifty-five degrees Celsius, although it should be appreciated that the temperature of air in aisles 128 and aisles 132 may vary widely. The temperature of air in aisles 128 and aisles 132 may vary depending upon factors including, but not limited to including, the area in data center 100 and the cooling capacity of CRAC 112

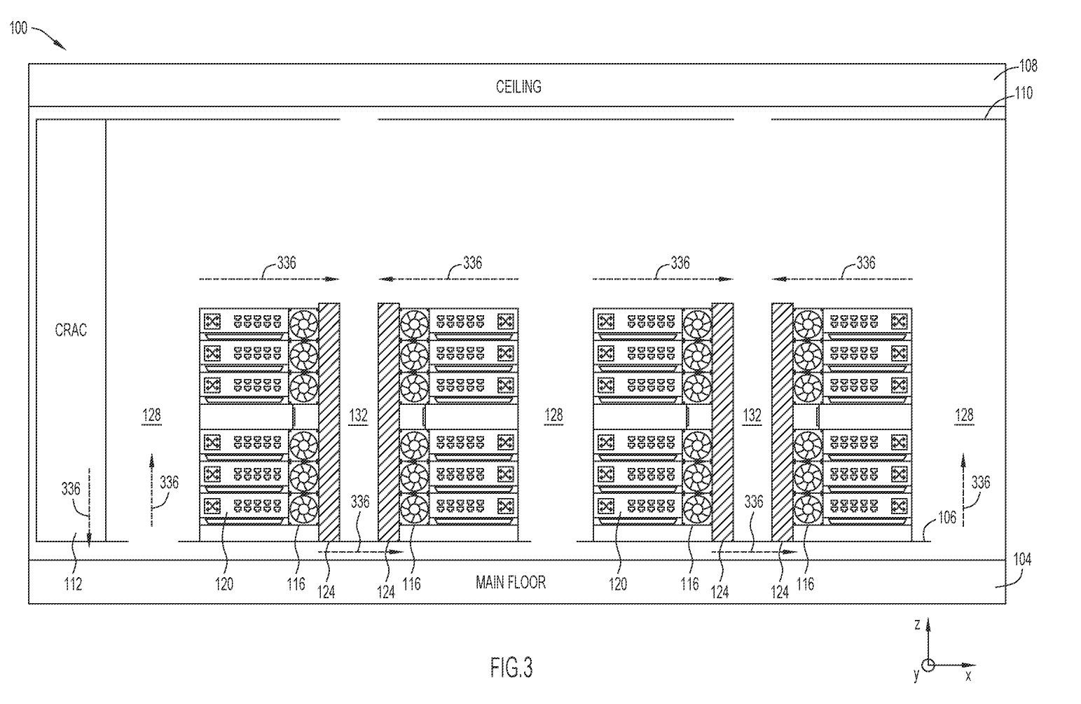

In general, copper foam thermoelectric heat exchangers 124 absorb an amount of heat generated by system hardware boxes 120, and the remaining heat that is not absorbed may cause air in aisles 132 to be warmed. The air flow associated with aisle 128 will be discussed below with reference to FIG. 3, and the air flow associated with aisle 132 will be discussed below with reference to FIG. 3.

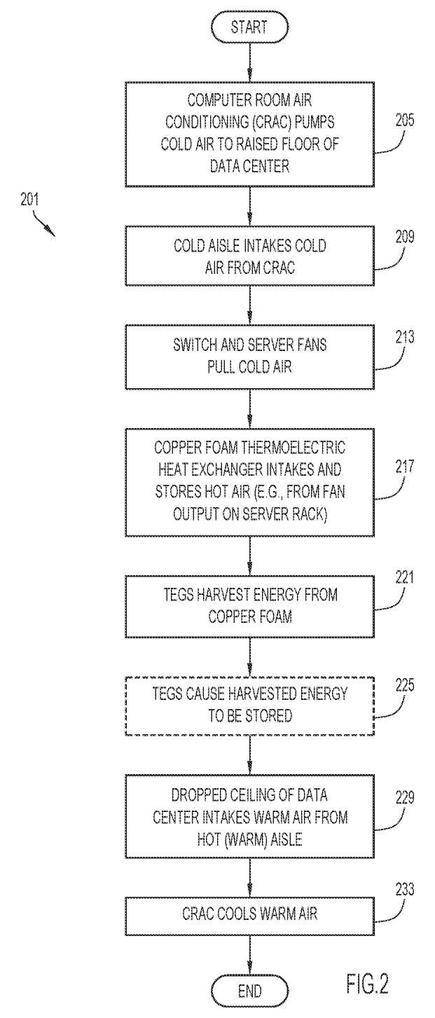

Referring next to FIG. 2, a method of cooling system hardware boxes, e.g., switches and servers, mounted on a server rack in a data center will be described in accordance with an embodiment. A method 201 of cooling system hardware boxes in a data center begins at a step 205 in which a CRAC pumps cold air to a raised floor of the data center. Once the CRAC pumps cold air or otherwise causes air within the data center to be cooled, one or more cold aisles in the data center intakes the cold air from the CRAC in a step 209.

System hardware boxes, as for example, switches and servers situated on a server rack generally include fans for cooling purposes. In a step 213, switch and server fans pull cold air into switches and servers. Switches and servers generally generate and/or dissipate hot air, and the cold air pulled in by fans may provide some cooling capabilities within the switches and servers. A copper foam thermoelectric heat exchanger intakes and stores hot air in a step 217. The hot air stored by the copper foam thermoelectric heat exchanger may include hot air from the output of switch and server fans. Copper foam included in the copper foam thermoelectric heat exchanger may intake and effectively store the heated air generated by switches and servers.

After the hot air is stored by the copper foam thermoelectric heat exchanger, one or more TEGs included in the copper foam thermoelectric heat exchanger may effectively harvest energy from the copper foam in a step 221. It should be appreciated that the hot air may be stored in the copper foam, and that TEGs in the copper foam thermoelectric heat exchanger may effectively convert the heat associated with the stored hot air into electrical energy. Due to the temperature gradient associated with the heat absorbed by copper foam, TEGs in the copper foam thermoelectric heat exchanger may sense the temperature gradient and efficiently convert the absorbed heat into energy, e.g., electrical energy. For example, the TEGs in the copper foam will sense the temperature gradient between the hot air, or air outputted by a server rack output, and air in a cold aisle, or the average temperature of a CRAC. Such a gradient, e.g., a temperature delta or difference, may result in a generated energy by the TEG.

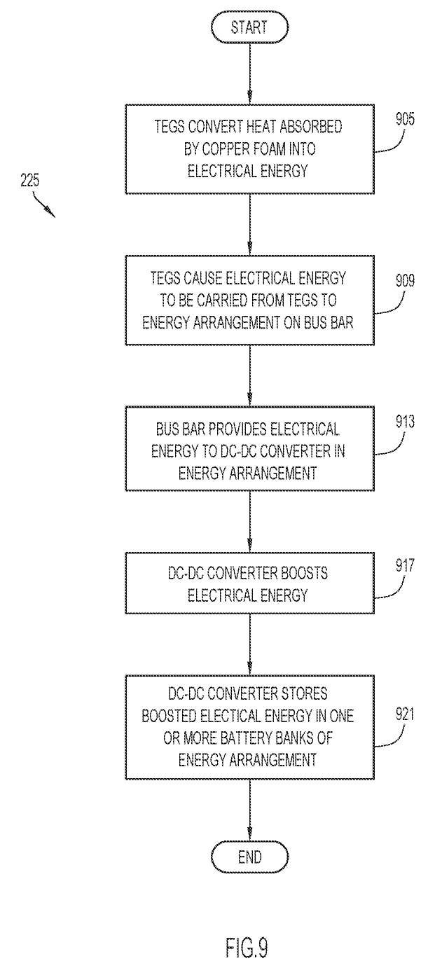

Optionally, in a step 225, the TEGs may cause the harvested energy to be stored. For example, the TEGs may provide the harvested energy to a battery that stores the harvested energy such that the battery may be used to provide energy as appropriate. The storage of harvested energy will be discussed below with respect to FIG. 9.

From step 221, or from optional step 225, process flow moves to a step 229 in which a dropped ceiling of the data center intakes warm air from a hot or warm aisle. The dropped ceiling may route or otherwise provide the warm air to the CRAC for cooling in a step 233. Once the CRAC cools the warm air, process flow returns to step 205 in which the CRAC pumps cold air to the raised floor of the data center.

With reference to FIG. 3, the flow of cold or cool air, as for example air provided by CRAC 112 of FIG. 1, will be described in accordance with an embodiment. The flow of cool air 336 through data center is such that cool air 336 is provided by CRAC 112 effectively to raised floor 106 such that cool air 336 may flow beneath server racks 116. Cool air 336 flows through aisles 128 in an upwards direct, i.e., a positive direction with respect to a z-axis. When cool air 336 effectively reaches tops of aisles 128, cool air 336 may flow towards aisles 132 with respect to an x-axis.

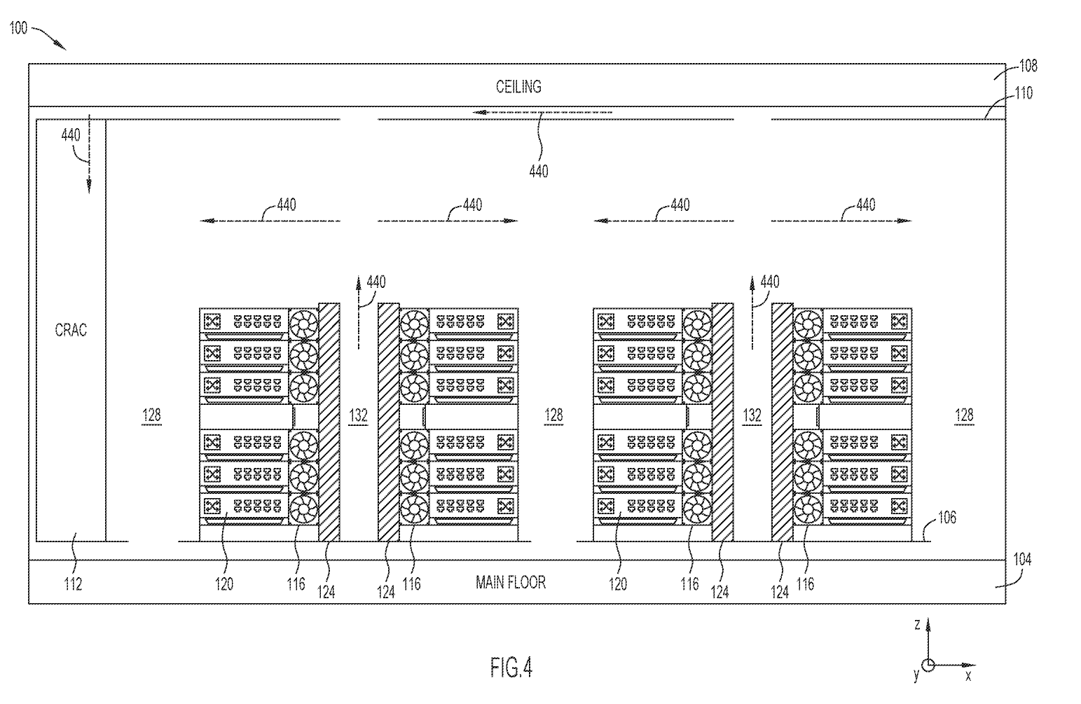

FIG. 4 is a diagrammatic representation of data center 100 which indicates a flow of warm air in accordance with an embodiment. A flow of warm air 440 is effectively originated when some portion of hot air generated by or dissipated by system hardware boxes 120 passes through copper foam thermoelectric heat exchangers 124. Warm air 440 flows through aisles 132 in an upwards direction. When warm air 440 effectively reaches tops of aisles 132, warm air 440 may flow towards aisles 128 with respect to an x-axis. Warm air 440 that reaches dropped ceiling 110 may flow towards CRAC 112, and may be cooled by CRAC 112. That is, cropped ceiling 110 intakes warm air 440 from aisles 132 and effectively routes warm air 440 to CRAC 112.

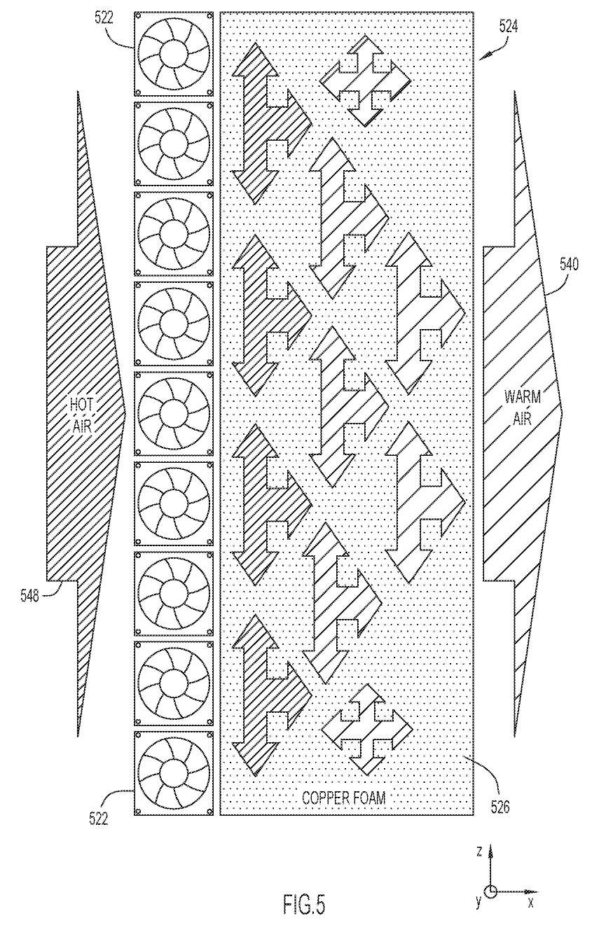

As previously mentioned, copper foam in a copper foam thermoelectric heat exchanger that is mounted on a server rack may absorb heat generated by system hardware boxes mounted on the server rack. Hence, the temperature of air entering the copper foam may be higher than the temperature of air effectively exiting from the copper foam. FIG. 5 is a diagrammatic representation of hot air being partially absorbed by a copper foam thermoelectric heat exchanger such that warm air passes out of the copper foam thermoelectric heat exchanger in accordance with an embodiment. Hot air 548 is exhausted or provided, as for example by switches and/or servers, to one or more fans 522. Fans 522 effectively blow hot air 548 into copper foam 526 of a copper foam thermoelectric heat exchanger 524. Some heat associated with hot air 548 is absorbed by copper foam 526, and the remaining air passes through copper foam 526 as warm air 540.

The thermal conductivity of copper foam 526, of the amount of energy that may be stored in copper, may be approximately 400 Watts per meter Kelvin (W/(m-K)). The specific heat of copper foam 526, or an amount of energy that may effectively be need to raise the temperature of copper, may be approximately 400 Joules per kilogram Kelvin (J/(kg-K)). Copper foam 526 may be formed using any suitable process which enables copper foam 526 to be porous. By way of example, copper foam 526 may be formed using a sintering-desolvation process to create pores. The porosity of copper foam may vary widely, e.g., between approximately twenty pores per inch (PPI) and approximately thirty-five PPI. As the porosity of copper foam 526 varies, the capacity for the copper foam 526 to absorb heat may vary. In general, a higher amount of PPI may provide better heat transfer than a lower amount of PPI.

FIG. 6 is a block diagram representation of a copper foam thermoelectric heat exchanger in accordance with an embodiment. Copper foam thermoelectric heat exchanger 624 includes copper foam 626 in which one or more TEGs 652a-n may be embedded. In one embodiment, one or more TEGs 652a-n may include Bi2Te3 semiconductors, and may each be configured to generate in the range of approximately ten Watts (W) of power for a temperature gradient of approximately two hundred degrees Kelvin. It should be appreciated, however, that the power generated for a given temperature gradient may vary and that the temperature gradient may vary. The number of TEGs 652a-n may vary widely depending upon the requirements of a data center such as data center 100 if FIG. 1. For example, when TEGs 652a-n are lower-capacity, a higher number of TEGs 652a-n may be embedded in copper foam 626 than when TEGs 652a-n are higher-capacity. The number of TEGs 652a-n embedded in copper foam 626 may vary depending upon factors which include, but are not limited to including, environmental parameters and/or the design of an overall system that uses copper foam thermoelectric heat exchanger 624. Further, TEGs 652a-n may be of different types and, as such, have different capacities, e.g., TEG 652a may be lower-capacity and TEG 652n may be higher-capacity.

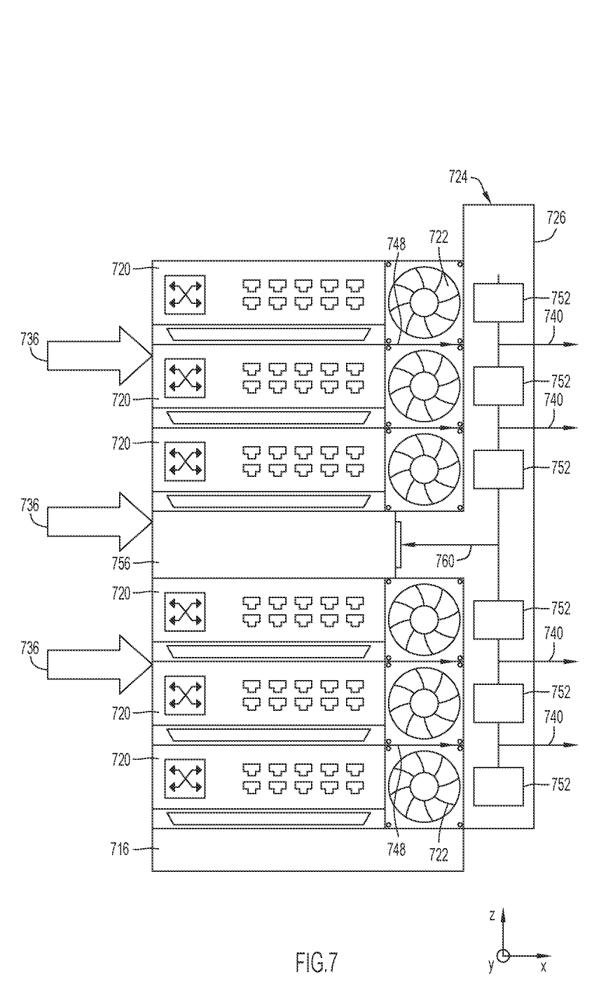

Referring next to FIG. 7, the flow of air and energy with respect to a server rack and a copper foam thermoelectric heat exchanger will be described in accordance with an embodiment. A server rack 716 or chassis that is suitable for use in a data center is arranged to support one or more system hardware boxes 720, one or more fans 722, a copper foam thermoelectric heat exchanger 724, and an energy arrangement 756. Copper foam thermoelectric heat exchanger 724 includes at least one piece of copper foam 726 in which one or more TEGs 752 are embedded. The at least one piece of copper foam 726 may be a panel of copper foam.

Cold air 736, e.g., air that is pumped out by a CRAC such as CRAC 112 of FIG. 1, is provided to cool system hardware boxes 720. As system hardware boxes 720 operate, hot air 748 flows out of system hardware boxes 720, as for example out of a backend of system hardware boxes 720. Hot air 748 flows out of hardware boxes 720 and through fans 722 to copper foam thermoelectric heat exchanger 724. Copper foam 726 absorbs heat from hot air 748, and one or more TEGs 752 may convert the stored heat into electrical energy. After some heat is absorbed by copper foam 726 from hot air 748, warm air 740 may effectively flow out of copper foam thermoelectric heat exchanger 724.

Once TEGs 752 convert heat absorbed by copper foam 726 into electrical energy, TEGs 752 provides the electrical energy to energy arrangement 756 through a bus bar 760. Energy arrangement 756 may store the electrical energy such that the electrical energy may be used, e.g., to supplement power consumed by hardware boxes 720.

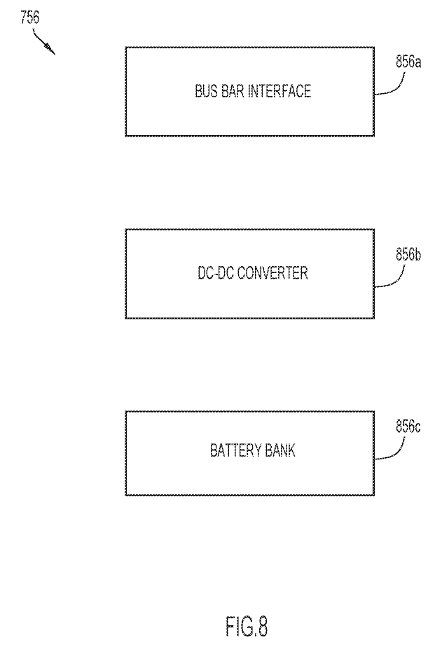

FIG. 8 is a diagrammatic representation of energy arrangement 756 in accordance with an embodiment. Energy arrangement 756 includes a bus bar interface 856a, a DC-DC converter 856b, and a battery bank 856c. Bus bar interface 856a is coupled to bus bar 760 of FIG. 7, and obtains harvested electrical energy provided on bus bar 760. DC-DC converter 856b is configured to boost electrical energy, and to cause the boosted electrical energy to be stored in battery bank 856c. The energy stored in battery bank 856c may be allocated for any suitable purpose. Suitable purposes include, but are not limited to including, providing power to system hardware boxes such as system hardware boxes 720 of FIG. 7.

With reference to FIG. 9, one method of causing energy effectively harvested from copper foam of a copper foam thermoelectric heat exchanger to be stored will be described in accordance with an embodiment. FIG. 9 is a process flow diagram which illustrates one method of causing harvested energy to be stored, e.g., optional step 225 of FIG. 2. A method or step 225 of causing harvested energy to be stored begins at a step 905 in which one or more TEGs of a copper foam thermoelectric heat exchanger converts heat, or heat flux, absorbed by copper foam into electric energy.

In a step 909, the TEGs cause electrical energy to be carried from the TEGs to an energy arrangement such as energy arrangement 756 of FIGS. 7 and 8. In one embodiment, the electrical energy is provided to the energy arrangement on a bus bar, as for example bus bar 760 of FIG. 7.

The bus bar provides electrical energy to a DC-DC converter in the energy arrangement 913, and the DC-DC converter boosts the electrical energy in a step 917. TEG output may be provided to a secondary circuit that effectively connects TEGs to a battery bank or other output device that converts a nominal TEG voltage to a higher voltage that may be commonly used for other applications. For example, a TEG may generate approximately ten mV that may be amplified or boosted to produce an approximately one volt output using a DC-DC converter or booster converter circuit. Once the electrical energy is boosted, the DC-DC converter causes the boosted electrical energy to be stored in one or more battery banks of the energy arrangement in a step 921, and the method of causing harvested energy to be stored is completed.

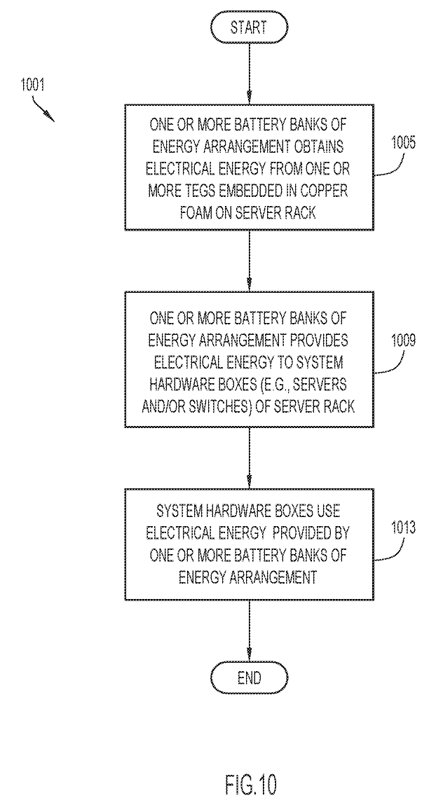

The boosted electrical energy stored in one or more battery banks of an energy arrangement, e.g., battery bank 856c of FIG. 8, may be utilized for any suitable purpose. In one embodiment, the boosted electrical energy may be used to power system hardware boxes, e.g., components in system hardware boxes which utilize a relatively low amount of energy. That is, electrical energy effectively derived or otherwise obtained from heat generated by system hardware boxes may be used to provide power to the system hardware boxes or to components in the system hardware boxes or associated with the system hardware boxes. For example, components such as an uninterrupted power supply (UPS), a battery bank, an external fan, and/or alarm circuitry may be powered by electrical energy stored in one or more battery banks of an energy arrangement. FIG. 10 is a process flow diagram which illustrates a method of using energy obtained from a copper foam thermoelectric heat exchanger in accordance with an embodiment. A method 1001 of utilizing energy obtained from a copper foam thermoelectric heat exchanger begins at a step 1005 in which one or more battery banks of an energy arrangement obtains electrical energy from one or more TEGs embedded in copper foam of a copper foam thermoelectric heat exchanger that is positioned on a server rack in a data center. As previously mentioned, the energy arrangement may obtain electrical energy from one or more TEGs on a bus bar, and a DC-DC convertor of the energy arrangement may boost the electrical energy before the boosted electrical energy is store in the one or more battery banks.

Once the one or more battery banks obtains the electrical energy, the one or more battery banks may provide the electrical energy to system hardware boxes of a server rack in a step 1009. For example, electrical energy may be provided to servers and/or switches.

After the electrical energy is provided to system hardware boxes, the system hardware boxes may use the electrical energy in a step 1013. In one embodiment, the system hardware boxes may use the electrical energy to effectively provide power to the system hardware boxes. The method of utilizing energy obtained from a copper foam thermoelectric heat exchanger is completed.

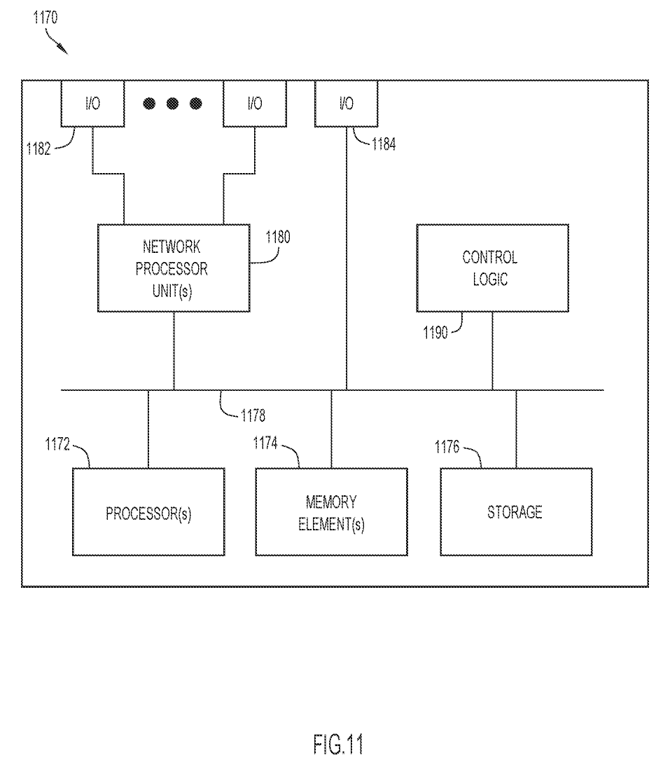

FIG. 11 is a hardware block diagram of a networking/computing device/apparatus/appliance/endpoint that may be cooled using the techniques described with respect to FIGS. 1-10, e.g., the networking/computing device/apparatus/appliance/endpoint may be embodied in a system hardware box stored on a server rack that is cooled using the techniques described above. It should be appreciated that FIG. 11 provides only an illustration of one example embodiment and does not imply any limitations with regard to the environments in which different example embodiments may be implemented. Many modifications to the depicted environment may be made.

In at least one embodiment, the computing device 1170 may be any apparatus that may include one or more processor(s) 1172, one or more memory element(s) 1174, storage 1176, a bus 1178, one or more network processor unit(s) 1180 interconnected with one or more network input/output (I/O) interface(s) 1182, one or more I/O interface(s) 1184, and control logic 1190. In various embodiments, instructions associated with logic for computing device 1170 may overlap in any manner and are not limited to the specific allocation of instructions and/or operations described herein.

In at least one embodiment, processor(s) 1172 is/are at least one hardware processor configured to execute various tasks, operations and/or functions for device 1170 as described herein according to software and/or instructions configured for device 1170. Processor(s) 1172 (e.g., a hardware processor) may execute any type of instructions associated with data to achieve the operations detailed herein. In one example, processor(s) 1172 may transform an element or an article (e.g., data, information) from one state or thing to another state or thing. Any of potential processing elements, microprocessors, digital signal processor, baseband signal processor, modem, PHY, controllers, systems, managers, logic, and/or machines described herein may be construed as being encompassed within the broad term 'processor'.

In at least one embodiment, one or more memory element(s) 1174 and/or storage 1176 is/are configured to store data, information, software, and/or instructions associated with device 1170, and/or logic configured for memory element(s) 1174 and/or storage 1176. For example, any logic described herein (e.g., control logic 1190) may, in various embodiments, be stored for device 1170 using any combination of memory element(s) 1174 and/or storage 1176. Note that in some embodiments, storage 1176 may be consolidated with one or more memory elements 1174 (or vice versa), or may overlap/exist in any other suitable manner. In one or more example embodiments, process data is also stored in the one or more memory elements 1174 for later evaluation and/or process optimization.

In at least one embodiment, bus 1178 may be configured as an interface that enables one or more elements of device 1170 to communicate in order to exchange information and/or data. Bus 1178 may be implemented with any architecture designed for passing control, data and/or information between processors, memory elements/storage, peripheral devices, and/or any other hardware and/or software components that may be configured for device 1170. In at least one embodiment, bus 1178 may be implemented as a fast kernel-hosted interconnect, potentially using shared memory between processes (e.g., logic), which may enable efficient communication paths between the processes.

In various embodiments, network processor unit(s) 1180 may enable communication between computing device 1170 and other systems, entities, etc., via network I/O interface(s) 1182 (wired and/or wireless) to facilitate operations discussed for various embodiments described herein. In various embodiments, network processor unit(s) 1180 may be configured as a combination of hardware and/or software, such as one or more Ethernet driver(s) and/or controller(s) or interface cards, Fibre Channel (e.g., optical) driver(s) and/or controller(s), wireless receivers/ transmitters/transceivers, baseband processor(s)/modem(s), and/or other similar network interface driver(s) and/or controller(s) now known or hereafter developed to enable communications between computing device 1170 and other systems, entities, etc. to facilitate operations for various embodiments described herein. In various embodiments, network I/O interface(s) 1182 may be configured as one or more Ethernet port(s), Fibre Channel ports, any other I/O port(s), and/or antenna(s)/antenna array(s) now known or hereafter developed. Thus, the network processor unit(s) 1180 and/or network I/O interface(s) 1182 may include suitable interfaces for receiving, transmitting, and/or otherwise communicating data and/or information in a network environment.

I/O interface(s) 1184 allow for input and output of data and/or information with other entities that may be connected to device 1170. For example, I/O interface(s) 1184 may provide a connection to external devices such as a keyboard, keypad, a touch screen, and/or any other suitable input device now known or hereafter developed. In some instances, external devices may also include portable computer readable (non-transitory) storage media such as database systems, thumb drives, portable optical or magnetic disks, and memory cards.

In various embodiments, control logic 1190 may include instructions that, when executed, cause processor(s) 1172 to perform operations, which may include, but not be limited to, providing overall control operations of computing device; interacting with other entities, systems, etc. described herein; maintaining and/or interacting with stored data, information, parameters, etc. (e.g., memory element(s), storage, data structures, databases, tables, etc.); combinations thereof; and/or the like to facilitate various operations for embodiments described herein.

The programs described herein (e.g., control logic 1190) may be identified based upon the application(s) for which they are implemented in a specific embodiment. However, it should be appreciated that any particular program nomenclature herein is used merely for convenience, and thus the embodiments herein should not be limited to use(s) solely described in any specific application(s) identified and/or implied by such nomenclature.

In the event the device 1170 is an endpoint (such as telephone, mobile phone, desk phone, conference endpoint, etc.), then the device 1170 may further include a sound processor, a speaker that plays out audio, and a microphone that detects audio. A sound processor may be a sound accelerator card or other similar audio processor that may be based on one or more ASICs and associated digital-to-analog and analog-to-digital circuitry to convert signals between the analog domain and digital domain. In some forms, the sound processor may include one or more digital signal processors (DSPs) and be configured to perform some or all of the operations of the techniques presented herein. The device 1170 may further include a video camera.

Although only a few embodiments have been described in this disclosure, it should be understood that the disclosure may be embodied in many other specific forms without departing from the spirit or the scope of the present disclosure. By way of example, a copper foam thermoelectric heat exchanger may be formed from any number of copper foam components. In other words, one or more panels of copper foam may be included in a copper foam thermoelectric heat exchanger. Panels of copper foam may be formed to dimensions appropriate for a particular server rack or server rack chassis. The number of TEGs included in each panel of copper foam in an overall copper foam thermoelectric heat exchanger may vary depending upon the requirements or demands of a particular system such as a server rack or a data center.

While boosted electrical energy stored in one or more battery banks of an energy arrangement of a server rack has been described as being used to substantially supplement energy used by servers and/or switches on the server rack, the boosted electrical energy is not limited to being provided to servers and/or switches on the server rack. For instance, the electrical energy stored in the one or more battery banks may be provided for general use within a data center, as for example to supplement power provided to a CRAC and/or to supplement power used by system hardware of other server racks. Further, the electrical energy stored in the one or more battery banks may be provided for use outside of a data center. That is, electrical energy that is effectively harvested from copper foam of a copper foam thermoelectric heat exchanger may be stored and allocated for use for any suitable purpose.

In some aspects, the techniques described herein relate to an apparatus including: a chassis; one or more heat-generating components, the one or more heat-generating components being carried on the chassis and arranged to generate heat; and a thermoelectric heat exchanger, the thermoelectric heat exchanger being carried on the chassis, the thermoelectric heat exchanger including copper foam and at least one thermoelectric generator (TEG), wherein the copper foam is arranged to absorb a first portion of the generated heat, and wherein the at least one TEG is configured to convert the first portion of the generated heat into electrical energy.

In some aspects, the techniques described herein relate to an apparatus wherein the heat includes a second portion, the second portion being arranged to pass through the copper foam.

In some aspects, the techniques described herein relate to an apparatus wherein the at least one TEG is embedded in the copper foam.

In some aspects, the techniques described herein relate to an apparatus further including: an energy arrangement, the energy arrangement being carried on the chassis, wherein the energy arrangement is configured to obtain the electrical energy from the thermoelectric heat exchanger.

In some aspects, the techniques described herein relate to an apparatus wherein the energy arrangement includes at least one battery bank, the battery bank being configured to store the electrical energy obtained from the thermoelectric heat exchanger, and wherein the energy arrangement is configured to provide the electrical energy to the one or more heat-generating components to power the one or more heat-generating components.

In some aspects, the techniques described herein relate to an apparatus wherein the one or more heat-generating components include at least one selected from a group including a server and a switch.

In some aspects, the techniques described herein relate to an apparatus wherein the copper foam has a porosity in a range of approximately twenty to approximately thirty-five pores per inch (PPI) and the at least one TEG is a Bi2Te3 semiconductor.

In some aspects, the techniques described herein relate to an apparatus including: a thermoelectric heat exchanger, the thermoelectric heat exchanger including copper foam and at least one thermoelectric generator (TEG), the at least one TEG being embedded in the copper foam, the copper foam being arranged to absorb a first portion of heat, wherein the at least one TEG is configured to convert the first portion of the generated heat into electrical energy and wherein a second portion of the heat passes through the copper foam; and an energy arrangement, the energy arrangement including a DC-DC converter and a battery bank, the energy arrangement being arranged to obtain the electrical energy and to store the electrical energy in the battery bank.

In some aspects, the techniques described herein relate to an apparatus wherein the DC-DC converter is arranged to boost the electrical energy before storing the electrical energy in the battery bank.

In some aspects, the techniques described herein relate to an apparatus wherein the heat is generated by hardware, and wherein the energy arrangement is configured to provide the electrical energy from the battery bank to the hardware.

In some aspects, the techniques described herein relate to an apparatus wherein the electrical energy is provided to the hardware to power the hardware.

In some aspects, the techniques described herein relate to an apparatus further including: a bus bar, the bus bar arranged to couple the at least one TEG to the energy arrangement.

In some aspects, the techniques described herein relate to an apparatus further including: a chassis, wherein the thermoelectric heat exchanger and the energy arrangement are coupled to the chassis.

In some aspects, the techniques described herein relate to a method including: obtaining, at a thermoelectric heat exchanger carried on a chassis, heat generated by a heat-generating component carried on the chassis, wherein the thermoelectric heat exchanger includes copper foam and at least one thermoelectric generator (TEG) embedded in the copper foam; absorbing a first portion of the heat in the copper foam; converting, using the at least one TEG, the first portion of the heat absorbed in the copper foam into electrical energy; providing, from the at least one TEG, the electrical energy to an energy arrangement, the energy arrangement being carried on the chassis, wherein the energy arrangement includes a battery bank; and storing the electrical energy in the battery bank.

In some aspects, the techniques described herein relate to a method further including: passing a second portion of the heat through the copper foam, wherein the second portion of the heat is not absorbed by the copper foam.

In some aspects, the techniques described herein relate to a method wherein the chassis is located in a data center and the heat-generating component is one selected from a group including a server and a switch, the method further including: cooling the second portion of the heat using a computer room air conditioner (CRAC), the CRAC being located in the data center.

In some aspects, the techniques described herein relate to a method further including: providing, from the battery bank, the electrical energy to the heat-generating component.

In some aspects, the techniques described herein relate to a method wherein the electrical energy is arranged to power the heat-generating component.

In some aspects, the techniques described herein relate to a method wherein the energy arrangement includes a DC-DC converter, and wherein providing the electrical energy to the energy arrangement include providing the electrical energy on a bus bar from the at least one TEG to the DC-DC converter.

In some aspects, the techniques described herein relate to a method further including: boosting the electrical energy using the DC-DC converter before storing the electrical energy in the battery bank using the DC-DC converter.

In various embodiments, entities as described herein may store data/information in any suitable volatile and/or non-volatile memory item (e.g., magnetic hard disk drive, solid state hard drive, semiconductor storage device, random access memory (RAM), read only memory (ROM), erasable programmable read only memory (EPROM), application specific integrated circuit (ASIC), etc.), software, logic (fixed logic, hardware logic, programmable logic, analog logic, digital logic), hardware, and/or in any other suitable component, device, element, and/or object as may be appropriate. Any of the memory items discussed herein should be construed as being encompassed within the broad term 'memory element'. Data/information being tracked and/or sent to one or more entities as discussed herein could be provided in any database, table, register, list, cache, storage, and/or storage structure: all of which may be referenced at any suitable timeframe. Any such storage options may also be included within the broad term 'memory element' as used herein.

Note that in certain example implementations, operations as set forth herein may be implemented by logic encoded in one or more tangible media that is capable of storing instructions and/or digital information and may be inclusive of non-transitory tangible media and/or non- transitory computer readable storage media (e.g., embedded logic provided in: an ASIC, digital signal processing (DSP) instructions, software [potentially inclusive of object code and source code], etc.) for execution by one or more processor(s), and/or other similar machine, etc. Generally, the storage 1176 and/or memory elements(s) 1174 may store data, software, code, instructions (e.g., processor instructions), logic, parameters, combinations thereof, and/or the like used for operations described herein. This includes the storage 1176 and/or memory elements(s) 1174 being able to store data, software, code, instructions (e.g., processor instructions), logic, parameters, combinations thereof, or the like that are executed to carry out operations in accordance with teachings of the present disclosure.

In some instances, software of the present embodiments may be available via a non- transitory computer useable medium (e.g., magnetic or optical mediums, magneto-optic mediums, CD-ROM, DVD, memory devices, etc.) of a stationary or portable program product apparatus, downloadable file(s), file wrapper(s), object(s), package(s), container(s), and/or the like. In some instances, non-transitory computer readable storage media may also be removable. For example, a removable hard drive may be used for memory/storage in some implementations. Other examples may include optical and magnetic disks, thumb drives, and smart cards that can be inserted and/or otherwise connected to a computing device for transfer onto another computer readable storage medium. The arrangements and modules described above may include, but are not limited to including, combinations of hardware, software, firmware, logic, code devices, and/or the like.

### Variations and Implementations

Embodiments described herein may include one or more networks, which can represent a series of points and/or network elements of interconnected communication paths for receiving and/or transmitting messages (e.g., packets of information) that propagate through the one or more networks. These network elements offer communicative interfaces that facilitate communications between the network elements. A network can include any number of hardware and/or software elements coupled to (and in communication with) each other through a communication medium. Such networks can include, but are not limited to, any local area network (LAN), virtual LAN (VLAN), wide area network (WAN) (e.g., the Internet), software defined WAN (SD-WAN), wireless local area (WLA) access network, wireless wide area (WWA) access network, metropolitan area network (MAN), Intranet, Extranet, virtual private network (VPN), Low Power Network (LPN), Low Power Wide Area Network (LPWAN), Machine to Machine (M2M) network, Internet of Things (IoT) network, Ethernet network/switching system, any other appropriate architecture and/or system that facilitates communications in a network environment, and/or any suitable combination thereof.

Networks through which communications propagate can use any suitable technologies for communications including wireless communications (e.g., 4G/5G/nG, IEEE 802.11 (e.g., Wi- Fi®/Wi-Fi6®), IEEE 802.16 (e.g., Worldwide Interoperability for Microwave Access (WiMAX)), Radio-Frequency Identification (RFID), Near Field Communication (NFC), Bluetooth™, mm.wave, Ultra-Wideband (UWB), etc.), and/or wired communications (e.g., T1 lines, T3 lines, digital subscriber lines (DSL), Ethernet, Fibre Channel, etc.). Generally, any suitable means of communications may be used such as electric, sound, light, infrared, and/or radio to facilitate communications through one or more networks in accordance with embodiments herein. Communications, interactions, operations, etc. as discussed for various embodiments described herein may be performed among entities that may directly or indirectly connected utilizing any algorithms, communication protocols, interfaces, etc. (proprietary and/or non-proprietary) that allow for the exchange of data and/or information.

In various example implementations, any entity or apparatus for various embodiments described herein can encompass network elements (which can include virtualized network elements, functions, etc.) such as, for example, network appliances, forwarders, routers, servers, switches, gateways, bridges, loadbalancers, firewalls, processors, modules, radio receivers/transmitters, or any other suitable device, component, element, or object operable to exchange information that facilitates or otherwise helps to facilitate various operations in a network environment as described for various embodiments herein. Note that with the examples provided herein, interaction may be described in terms of one, two, three, or four entities. However, this has been done for purposes of clarity, simplicity and example only. The examples provided should not limit the scope or inhibit the broad teachings of systems, networks, etc. described herein as potentially applied to a myriad of other architectures.

Communications in a network environment can be referred to herein as 'messages', 'messaging', 'signaling', 'data', 'content', 'objects', 'requests', 'queries', 'responses', 'replies', etc. which may be inclusive of packets. As referred to herein and in the claims, the term 'packet' may be used in a generic sense to include packets, frames, segments, datagrams, and/or any other generic units that may be used to transmit communications in a network environment. Generally, a packet is a formatted unit of data that can contain control or routing information (e.g., source and destination address, source and destination port, etc.) and data, which is also sometimes referred to as a 'payload', 'data payload', and variations thereof. In some embodiments, control or routing information, management information, or the like can be included in packet fields, such as within header(s) and/or trailer(s) of packets. Internet Protocol (IP) addresses discussed herein and in the claims can include any IP version 4 (IPv4) and/or IP version 6 (IPv6) addresses.

To the extent that embodiments presented herein relate to the storage of data, the embodiments may employ any number of any conventional or other databases, data stores or storage structures (e.g., files, databases, data structures, data or other repositories, etc.) to store information.

Note that in this Specification, references to various features (e.g., elements, structures, nodes, modules, components, engines, logic, steps, operations, functions, characteristics, etc.) included in 'one embodiment', 'example embodiment', 'an embodiment', 'another embodiment', 'certain embodiments', 'some embodiments', 'various embodiments', 'other embodiments', 'alternative embodiment', and the like are intended to mean that any such features are included in one or more embodiments of the present disclosure, but may or may not necessarily be combined in the same embodiments. Note also that a module, engine, client, controller, function, logic or the like as used herein in this Specification, can be inclusive of an executable file comprising instructions that can be understood and processed on a server, computer, processor, machine, compute node, combinations thereof, or the like and may further include library modules loaded during execution, object files, system files, hardware logic, software logic, or any other executable modules.

It is also noted that the operations and steps described with reference to the preceding figures illustrate only some of the possible scenarios that may be executed by one or more entities discussed herein. Some of these operations may be deleted or removed where appropriate, or these steps may be modified or changed considerably without departing from the scope of the presented concepts. In addition, the timing and sequence of these operations may be altered considerably and still achieve the results taught in this disclosure. The preceding operational flows have been offered for purposes of example and discussion. Substantial flexibility is provided by the embodiments in that any suitable arrangements, chronologies, configurations, and timing mechanisms may be provided without departing from the teachings of the discussed concepts.

As used herein, unless expressly stated to the contrary, use of the phrase 'at least one of', 'one or more of', 'and/or', variations thereof, or the like are open-ended expressions that are both conjunctive and disjunctive in operation for any and all possible combination of the associated listed items. For example, each of the expressions 'at least one of X, Y and Z', 'at least one of X, Y or Z', 'one or more of X, Y and Z', 'one or more of X, Y or Z' and 'X, Y and/or Z' can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Note that in this Specification, references to various features (e.g., elements, structures, nodes, modules, components, engines, logic, steps, operations, functions, characteristics, etc.) included in 'one embodiment', 'example embodiment', 'an embodiment', 'another embodiment', 'certain embodiments', 'some embodiments', 'various embodiments', 'other embodiments', 'alternative embodiment', and the like are intended to mean that any such features are included in one or more embodiments of the present disclosure, but may or may not necessarily be combined in the same embodiments.

Each example embodiment disclosed herein has been included to present one or more different features. However, all disclosed example embodiments are designed to work together as part of a single larger system or method. This disclosure explicitly envisions compound embodiments that combine multiple previously-discussed features in different example embodiments into a single system or method.

Additionally, unless expressly stated to the contrary, the terms 'first', 'second', 'third', etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, 'first X' and 'second X' are intended to designate two 'X' elements that are not necessarily limited by any order, rank, importance, temporal sequence, or hierarchy of the two elements. Further as referred to herein, 'at least one of' and 'one or more of' can be represented using the '(s)' nomenclature (e.g., one or more element(s)).

As used herein, the terms “approximately,” “generally,” “substantially,” and so forth, are intended to convey that the property value being described may be within a relatively small range of the property value, as those of ordinary skill would understand. For example, when a property value is described as being “approximately” equal to (or, for example, “substantially similar” to) a given value, this is intended to convey that the property value may be within +/- 5%, within +/- 4%, within +/- 3%, within +/- 2%, within +/- 1%, or even closer, of the given value.

Similarly, when a given feature is described as being “substantially parallel” to another feature, “generally perpendicular” to another feature, and so forth, this is intended to convey that the given feature is within +/- 5%, within +/- 4%, within +/- 3%, within +/- 2%, within +/- 1%, or even closer, to having the described nature, such as being parallel to another feature, being perpendicular to another feature, and so forth. Mathematical terms, such as “parallel” and “perpendicular,” should not be rigidly interpreted in a strict mathematical sense, but should instead be interpreted as one of ordinary skill in the art would interpret such terms. For example, one of ordinary skill in the art would understand that two lines that are substantially parallel to each other are parallel to a substantial degree, but may have minor deviation from exactly parallel.

One or more advantages described herein are not meant to suggest that any one of the embodiments described herein necessarily provides all of the described advantages or that all the embodiments of the present disclosure necessarily provide any one of the described advantages. Numerous other changes, substitutions, variations, alterations, and/or modifications may be ascertained to one skilled in the art and it is intended that the present disclosure encompass all such changes, substitutions, variations, alterations, and/or modifications as falling within the scope of the appended claims.

What is claimed is:

1. An apparatus comprising:
a chassis;
one or more heat-generating components, the one or more heat-generating components being carried on the chassis and arranged to generate heat; and
a thermoelectric heat exchanger, the thermoelectric heat exchanger being carried on the chassis, the thermoelectric heat exchanger including copper foam and at least one thermoelectric generator (TEG), wherein the copper foam is arranged to absorb a first portion of the generated heat, and wherein the at least one TEG is configured to convert the first portion of the generated heat into electrical energy.

2. The apparatus of claim 1 wherein the heat includes a second portion, the second portion being arranged to pass through the copper foam.

3. The apparatus of claim 1 wherein the at least one TEG is embedded in the copper foam.

4. The apparatus of claim 3 further including:
an energy arrangement, the energy arrangement being carried on the chassis, wherein the energy arrangement is configured to obtain the electrical energy from the thermoelectric heat exchanger.

5. The apparatus of claim 4 wherein the energy arrangement includes at least one battery bank, the at least one battery bank being configured to store the electrical energy obtained from the thermoelectric heat exchanger, and wherein the energy arrangement is configured to provide the electrical energy to the one or more heat-generating components to power the one or more heat-generating components.

6. The apparatus of claim 1 wherein the one or more heat-generating components include at least one selected from a group including a server and a switch.

7. The apparatus of claim 1 wherein the copper foam has a porosity in a range of approximately twenty to approximately thirty-five pores per inch (PPI) and the at least one TEG is a Bi2Te3 semiconductor.

8. An apparatus comprising:
a thermoelectric heat exchanger, the thermoelectric heat exchanger including copper foam and at least one thermoelectric generator (TEG), the at least one TEG being embedded in the copper foam, the copper foam being arranged to absorb a first portion of heat, wherein the at least one TEG is configured to convert the first portion of the generated heat into electrical energy and wherein a second portion of the heat passes through the copper foam; and
an energy arrangement, the energy arrangement including a DC-DC converter and a battery bank, the energy arrangement being arranged to obtain the electrical energy and to store the electrical energy in the battery bank.

9. The apparatus of claim 8 wherein the DC-DC converter is arranged to boost the electrical energy before storing the electrical energy in the battery bank.

10. The apparatus of claim 8 wherein the heat is generated by hardware, and wherein the energy arrangement is configured to provide the electrical energy from the battery bank to the hardware.

11. The apparatus of claim 10 wherein the electrical energy is provided to the hardware to power the hardware.

12. The apparatus of claim 8 further including:
a bus bar, the bus bar arranged to couple the at least one TEG to the energy arrangement.

13. The apparatus of claim 8 further including:
a chassis, wherein the thermoelectric heat exchanger and the energy arrangement are coupled to the chassis.

14. A method comprising:
obtaining, at a thermoelectric heat exchanger carried on a chassis, heat generated by a heat-generating component carried on the chassis, wherein the thermoelectric heat exchanger includes copper foam and at least one thermoelectric generator (TEG) embedded in the copper foam;
absorbing a first portion of the heat in the copper foam;
converting, using the at least one TEG, the first portion of the heat absorbed in the copper foam into electrical energy;
providing, from the at least one TEG, the electrical energy to an energy arrangement, the energy arrangement being carried on the chassis, wherein the energy arrangement includes a battery bank; and
storing the electrical energy in the battery bank.

15. The method of claim 14 further including:
passing a second portion of the heat through the copper foam, wherein the second portion of the heat is not absorbed by the copper foam.

16. The method of claim 15 wherein the chassis is located in a data center and the heat-generating component is one selected from a group including a server and a switch, the method further including:
cooling the second portion of the heat using a computer room air conditioner (CRAC), the CRAC being located in the data center.

17. The method of claim 16 further including:
providing, from the battery bank, the electrical energy to the heat-generating component.

18. The method of claim 17 wherein the electrical energy is arranged to power the heat-generating component.

19. The method of claim 14 wherein the energy arrangement includes a DC-DC converter, and wherein providing the electrical energy to the energy arrangement include providing the electrical energy on a bus bar from the at least one TEG to the DC-DC converter.

20. The method of claim 19 further including:
boosting the electrical energy using the DC-DC converter before storing the electrical energy in the battery bank using the DC-DC converter.
